(19) United States
(12) Patent Application Publication
(10) Pub. No.: US 2013/0269753 A1
(43) Pub. Date: Oct. 17, 2013

(54) MOUNTING ASSEMBLIES, SOLAR TRACKERS, AND RELATED METHODS

(71) Applicant: Ronald P. Corio, Albuquerque, NM (US)

(72) Inventor: Ronald P. Corio, Albuquerque, NM (US)

(21) Appl. No.: 13/864,008

(22) Filed: Apr. 16, 2013

Related U.S. Application Data
(60) Provisional application No. 61/625,470, filed on Apr. 17, 2012.

(51) Int. Cl. H01L 31/042

(52) U.S. Cl. CPC H01L 31/0422
USPC 136/246; 211/164

(57) ABSTRACT

Mounting assemblies, solar trackers, and methods of reducing the torque load of a solar tracker are provided. A mounting assembly comprises at least one support column, a torsion beam connected to the support column, and a mounting rack attached to the torsion beam. A longitudinal pivot axis extends through the torsion beam. The mounting rack has a substantially flat mounting surface and a curved rear surface such that a weight of one or more components mounted thereto is shifted toward the pivot axis.

### CROSS-REFERENCE TO RELATED APPLICATION

This application is a non-provisional of and claims priority to U.S. Application Ser. No. 61/625,470, filed Apr. 17, 2012, which is hereby incorporated by reference in its entirety.

### FIELD

The present disclosure relates to mounting assemblies. In addition, the present disclosure relates to solar trackers and related methods.

### BACKGROUND

Most photovoltaic (“PV”) modules are quite heavy because they use glass to encase the PV cells. A solar mounting system, therefore, must be able to withstand the weight of an array of one or more PV modules. Thus, structural improvements that add strength and make more efficient use of material can create significant cost advantages.

In addition to supporting heavy solar arrays, solar tracking equipment must also be able to move the solar array so it tracks the sun. This can require motors with significant horsepower. Existing solar tracking equipment are structured so the center of gravity of the mounted solar array is at a distance from the pivot axis of the tracker.

Many tracking systems seek to minimize this center of gravity offset by taking one of two approaches. The first is to incorporate a continuous beam supported by multiple supports and bearings. These designs typically minimize the profile height of the structural members that support the modules in order to reduce the overhung weight of the system. They suffer from a limitation on span supports, i.e., un-optimized support members due to the structural member profile minimization. Moreover, they still suffer from a large overhung weight component, since all the modules are mounted at a fixed distance from the pivot axis.

The second approach is to incorporate a segmented rotating beam separated by offset bearings at the supports. These trackers are not limited in the profile size of the structural members since they “correct” for the imbalance at the bearings. They typically adjust the position of the pivoting axis to balance the weight of the system about the center of gravity. However, a significant disadvantage of these designs is that they typically require fixed lengths of rotating beams with welded or elaborately bolted offset bearing connections at every support, which substantially increases their cost and reduces their manufacturing and installation flexibility.

Accordingly, there is a need for a mounting system that balances the weight of the mounted components more evenly over the system. There is also a need for a solar tracker that requires less force to rotate to obviate the need for high horsepower motors. There is a further need for a method of reducing the torque load of a solar tracker. There is also a need for structural improvements that add strength to the solar tracker and make more efficient use of material. Finally, there is a need for a solar tracker that reduces the overhung weight of the solar array to minimize the structural material required for the tracker.

### SUMMARY

The embodiments of the present disclosure alleviate to a great extent the disadvantages of known mounting systems and solar trackers by providing a mounting assembly and solar tracker with a rigid structural design including a mounting rack with a substantially flat mounting surface and a curved rear surface to add strength and make more efficient use of materials.

In addition, mounting assemblies and solar trackers are provided in which the mounting rack has a curved mounting surface and/or a curved rear surface which causes the weight of the components mounted thereto such as solar modules to be shifted toward a central pivot axis. More particularly, the weight of the mounted components is shifted such that the center of gravity of the mounting rack and the components is at or near the pivot axis, thereby creating a balanced configuration. Disclosed embodiments balance the weight of the mounted components more evenly over the rotating beam and result in less force required to rotate the solar tracker.

In exemplary embodiments, a mounting assembly comprises at least one support column, a torsion beam connected to the support column, and a mounting rack attached to the torsion beam. A longitudinal pivot axis extends through the torsion beam. The torsion beam may be rotatably connected to the support column such that the mounting rack rotates about the pivot axis. The mounting rack has a substantially flat mounting surface and a curved rear surface. The mounting rack may comprise a straight front frame support and a curved back frame support. The mounted components may include one or more solar modules.

Exemplary embodiments of a solar tracker comprise at least one support column, a torsion beam connected to the support column, a mounting rack attached to the torsion beam, and one or more solar modules mounted to the mounting rack. A longitudinal pivot axis extends through the torsion beam. The torsion beam may be rotatably connected to the support column such that the mounting rack rotates about the pivot axis. Alternatively, the torsion beam may be fixedly attached to the support column such that the mounting rack is in a fixed position relative to the support column. The mounting rack has a curved rear surface and a substantially flat mounting surface, and the solar modules are mounted to the mounting surface of the mounting rack. The mounting rack may include a substantially flat front frame support and a curved back frame support.

Exemplary embodiments of a mounting assembly comprise at least one support column, a torsion beam connected to the support column, and a mounting rack attached to the torsion beam. A longitudinal pivot axis extends through the torsion beam. The torsion beam may be rotatably connected to the support column such that the mounting rack rotates about the pivot axis. The mounting rack has a rear surface and a curved mounting surface such that a weight of one or more components mounted thereto is shifted toward the pivot axis. In exemplary embodiments, the components comprise one or more solar modules.

In exemplary embodiments, the weight of the mounted components is shifted such that the center of gravity of the mounting rack and the components is at or near the pivot axis. The mounting assembly may further comprise a balance axis intersecting and perpendicular to the pivot axis. A balanced configuration may be achieved when a first portion of the weight of the mounted components above the balance axis multiplied by a distance between the balance axis and the curved mounting surface is substantially equal to a second portion of the weight of the mounted components below the balance axis multiplied by a distance between the balance axis and the rear surface of the mounting rack.

In exemplary embodiments, the rear surface of the mounting rack is substantially straight, and the mounting rack may comprise a curved front frame support and a straight back frame support. The curved front frame support may include one more angles along its length. In exemplary embodiments, the rear surface of the mounting rack is curved, and the mounting rack may comprise a curved front frame support and a curved back frame support. The curved back frame support may include one or more angles along its length.

Exemplary embodiments of a solar tracker comprise at least one support column, a torsion beam connected to the support column, a mounting rack attached to the torsion beam, and one or more solar modules mounted to the mounting rack. A longitudinal pivot axis extends through the torsion beam. The mounting rack has rear surface and a curved mounting surface, and the one or more solar modules are mounted to the curved mounting surface of the mounting rack. By being mounted to the curved surface of the mounting rack, a weight of the one or more solar modules is shifted toward the pivot axis.

In exemplary embodiments, the weight of the solar modules is shifted such that the center of gravity of the mounting rack and the solar modules is at or near the pivot axis. The solar tracker may further comprise a balance axis intersecting and perpendicular to the pivot axis. A balanced configuration may be achieved when a first portion of the weight of the solar modules above the balance axis multiplied by a distance between the balance axis and the curved mounting surface is substantially equal to a second portion of the weight of the solar modules below the balance axis multiplied by a distance between the balance axis and the rear surface of the mounting rack.

In exemplary embodiments, the torsion beam is rotatably connected to the support column such that the mounting rack rotates about the pivot axis. The rear surface of the mounting rack may be substantially straight. In exemplary embodiments, the rear surface of the mounting rack is curved, and the mounting rack may comprise a curved front frame support and a curved back frame support.

Exemplary embodiments include methods of reducing the torque load of a solar tracker comprising providing at least one support column, providing a torsion beam rotatably connected to the support column, providing a mounting rack having a rear surface and a curved mounting surface, and mounting one or more solar modules to the curved mounting surface of the mounting rack. A longitudinal pivot axis extends through the torsion beam. The mounting rack is rotatably connected to the torsion beam such that the mounting rack rotates about the pivot axis. By being mounted to the curved surface of the mounting rack, the load of the one or more solar modules is shifted toward the pivot axis and the torque load about the pivot axis is reduced.

Exemplary embodiments further comprise the step of shifting the load of the one or more solar modules such that the center of gravity of the mounting rack and the solar modules is at or near the pivot axis. Exemplary methods further comprise balancing the solar tracker by rotating the mounting rack such that a first portion of the weight of the solar modules above a balance axis intersecting and perpendicular to the pivot axis multiplied by a distance between the balance axis and the curved mounting surface is substantially equal to a second portion of the weight of the solar modules below the balance axis multiplied by a distance between the balance axis and the rear surface of the mounting rack. The solar tracker may also be rotated to track the movement of the sun.

Accordingly, it is seen that mounting assemblies, solar trackers, and related methods of reducing torque load are provided. The disclosed devices and methods shift the weight of the mounted components such that the center of gravity of the mounting rack and the components is at or near the pivot axis, thereby creating a more balanced system and reducing the overhung weight of the mounted components. These and other features and advantages will be appreciated from review of the following detailed description, along with the accompanying figures in which like reference numbers refer to like parts throughout.

### BRIEF DESCRIPTION OF THE DRAWINGS

The foregoing and other objects of the disclosure will be apparent upon consideration of the following detailed description, taken in conjunction with the accompanying drawings, in which:

FIG. 1 is a front perspective view of an exemplary embodiment of a mounting assembly in accordance with the present disclosure;

FIG. 2 is a rear perspective view of an exemplary embodiment of a mounting assembly in accordance with the present disclosure;

FIG. 3 is a side cross-sectional view of an exemplary embodiment of a mounting assembly in accordance with the present disclosure;

FIG. 4 is a side cross-sectional view of an exemplary embodiment of a mounting assembly in accordance with the present disclosure;

FIG. 5 is a front perspective view of an exemplary embodiment of a mounting assembly in accordance with the present disclosure;

FIG. 6 is a rear perspective view of an exemplary embodiment of a mounting assembly in accordance with the present disclosure;

FIG. 7 is a side cross-sectional view of an exemplary embodiment of a mounting assembly in accordance with the present disclosure;

FIG. 8 is a front perspective view of an exemplary embodiment of a mounting assembly in accordance with the present disclosure;

FIG. 9 is a rear perspective view of an exemplary embodiment of a mounting assembly in accordance with the present disclosure;

FIG. 10 is a side cross-sectional view of an exemplary embodiment of a mounting assembly in accordance with the present disclosure;

FIG. 11 is a rear perspective view of an exemplary embodiment of a mounting assembly in accordance with the present disclosure; and

FIG. 12 is a side cross-sectional view of an exemplary embodiment of a mounting assembly in accordance with the present disclosure.

### DETAILED DESCRIPTION

In the following paragraphs, embodiments will be described in detail by way of example with reference to the accompanying drawings, which are not drawn to scale, and the illustrated components are not necessarily drawn proportionately to one another. Throughout this description, the embodiments and examples shown should be considered as exemplars, rather than as limitations of the present disclosure. As used herein, the “present disclosure” refers to any one of the embodiments described herein, and any equivalents. Furthermore, reference to various aspects of the disclosure throughout this document does not mean that all claimed embodiments or methods must include the referenced aspects.

In general, embodiments of the present disclosure relate to mounting assemblies, solar trackers, and associated methods. Exemplary embodiments further include a substantially flat front rack surface with a curved rear surface. Exemplary embodiments include a curved front rack design for mounting PV modules, either unframed or framed, onto a rotating solar tracker beam or a beam of a fixed mounting rack. The curved front and/or rear surface of the PV rack provides significant advantages over existing solar tracker designs, including additional strength, more efficient use of material, rigid structural design, moving the center of gravity closer to the pivot axis of the tracker to reduce overhung weight and minimize the amount of material needed for the tracker. These and additional advantages are explained in more detail below.

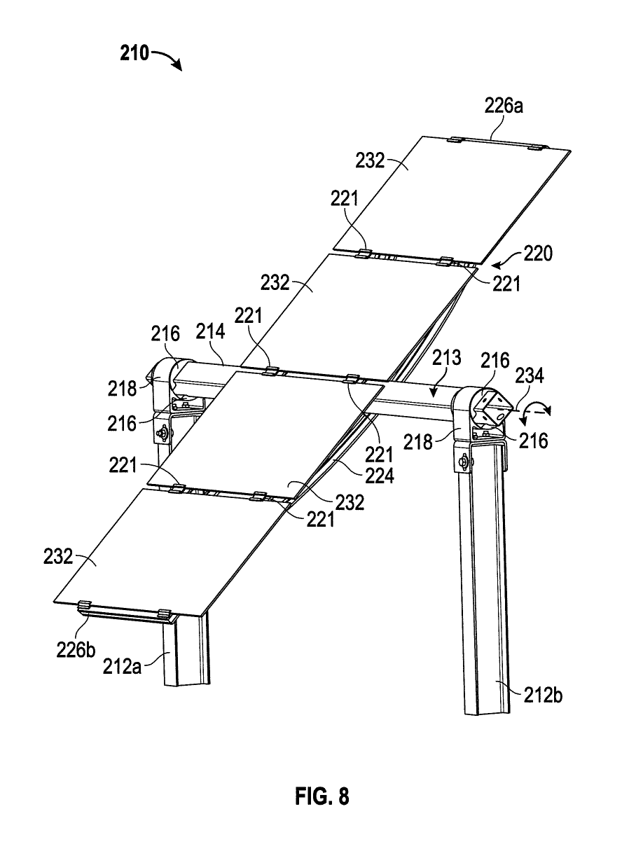

Exemplary embodiments of a mounting assembly 210 or solar tracker 210 will be described with reference to FIGS. 8-10. Mounting assembly 210 comprises at least one support column 212 and, in exemplary embodiments, comprises two spaced apart support columns 212a and 212b. A torsion beam 214 is connected to the support columns 212a, 212b by a bearing 216 and bearing housing 218 arrangement including any suitable fasteners. A pivot axis 234 extends longitudinally through the torsion beam 214, and the torsion beam 214 may pivot or rotate about the pivot axis 234.

A mounting rack 220 includes front frame support 222 and rear frame support 224 and is attached to the torsion beam 214. The mounting rack 220 may be rotatably connected to the torsion beam 214 so it can be pivoted or rotated about the pivot axis 234. Alternatively, the mounting rack 220 could be fixedly attached to the torsion beam 214 to form a fixed mounting assembly or solar tracker. The front frame support 222 is disposed upon a first side 213 of the torsion beam 214, and the rear frame support 224 is disposed upon a second opposite side 215 of the torsion beam 214. The front and rear frame supports 222, 224 of the mounting rack 220 may be held together by top and bottom end frame supports 226a, 226b, and a frame connector 227 may also be used to secure the connection of the frame support 222, 224 of the mounting rack 220 to the torsion beam 214.

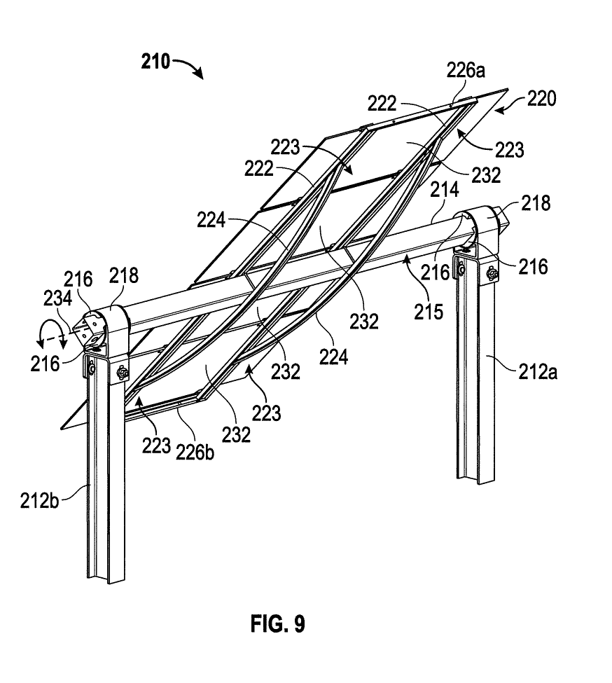

Alternatively, as best seen in FIG. 9, the rear frame support 224 may be attached to the front frame support 222 at one or more intermediate locations 223 along the length of the front frame support 222 displaced from the ends of the front frame support 222. The outer surface of the rear frame support 224 of the mounting rack 220 constitutes the rear surface 228 of the rack, and the outer surface of the front frame support 222 constitutes the mounting surface 230 of the mounting rack 220.

In exemplary embodiments, the mounting assembly is a solar tracker 210, and the components mounted to the mounting surface 230 of the mounting rack 220 are solar modules 232. The solar modules 232 may be mounted to the flat mounting surface 230 of the mounting rack 220 using movable mounting clips 221. Exemplary mounting racks 220 have a front frame support 222 that is a substantially flat member, and a rear frame support 224 that is a curved member. Thus, the mounting surface 230 of the mounting rack 220 may be a substantially flat surface, and the rear surface 228 of the mounting rack is curved. The rear frame support 224 may form a curve by any structural features, including but not limited to a continuous curve along its length, one or more angles or bends along its length, one or more interrupted curves along its length, and/or one more shorter frame support members connected at angles to from a full frame support.

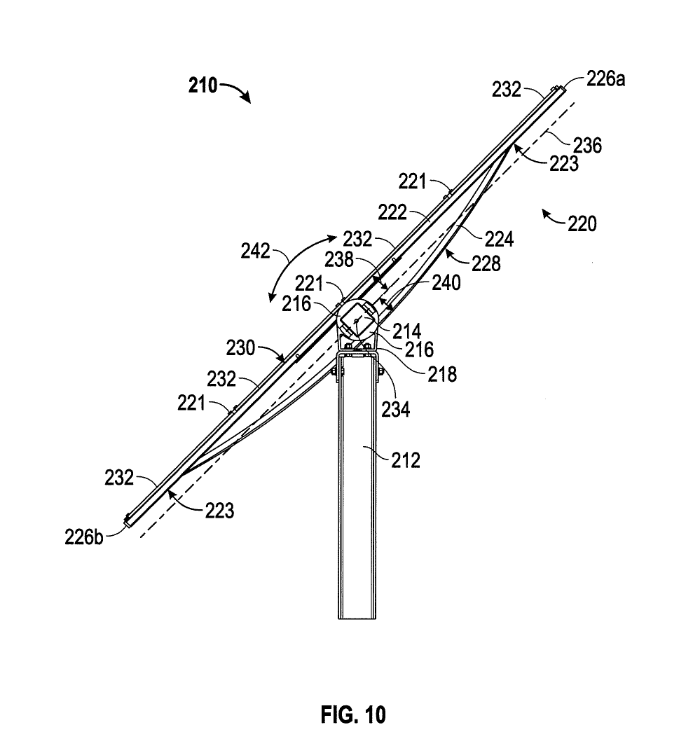

Turning to FIG. 10, it can be seen that the mounting assembly 210 may have a balance axis 236 running perpendicular to the pivot axis 234 and intersecting the pivot axis 234. The mounting assembly 210 further includes a first distance 238, which is the distance between the balance axis 236 and the curved mounting surface 230 of the mounting rack 220, and a second distance 240, which is the distance between the balance axis 236 and the rear surface 228 of the mounting rack 220.

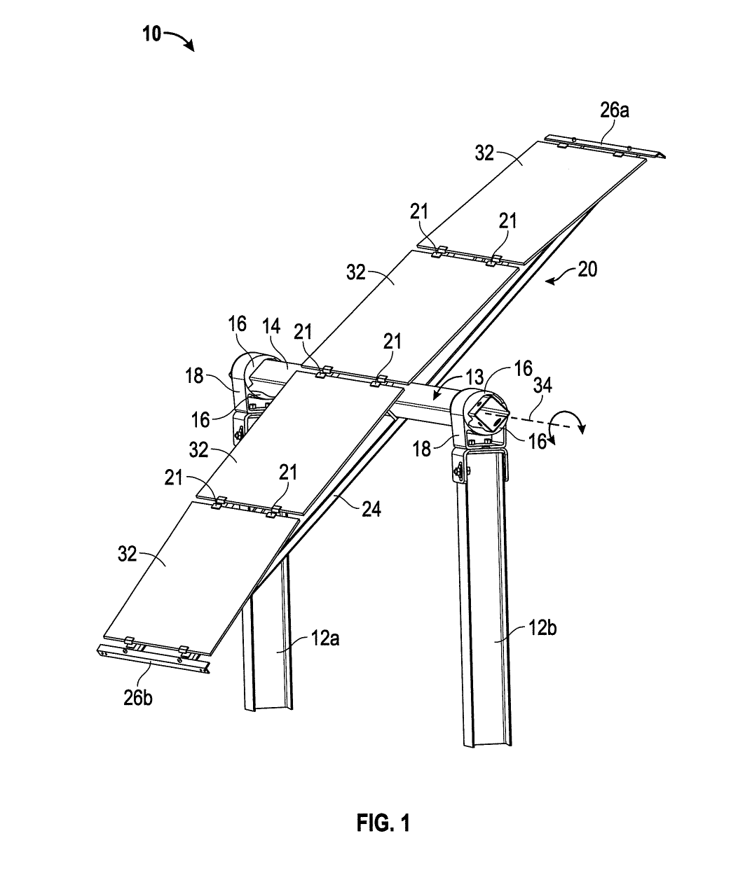

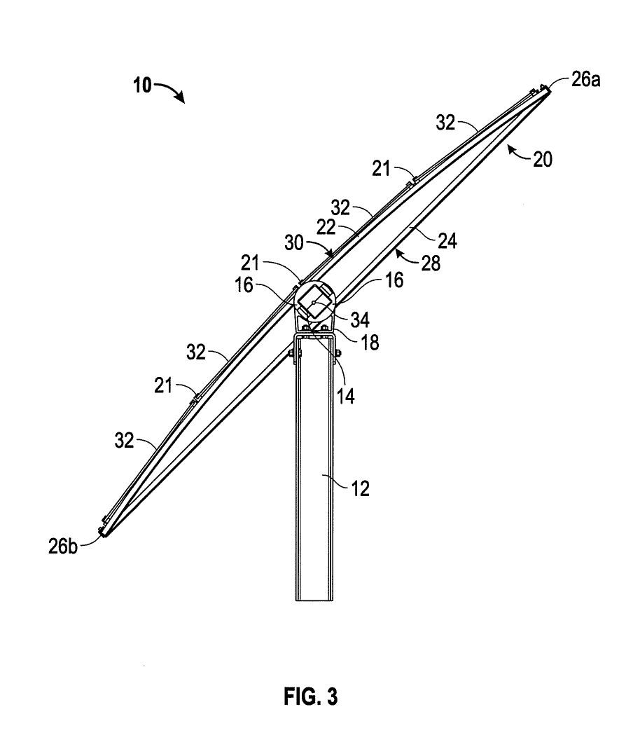

With reference to FIGS. 1-4, exemplary embodiments of a mounting assembly or solar tracker will be described. Mounting assembly 10 comprises at least one support column 12, which may be any shape and composed of any material so long as it is capable of supporting the mounting assembly and components mounted thereto. Exemplary embodiments of the mounting assembly 10 include two spaced part support columns 12a and 12b. A torsion beam 14 is connected to the support column 12. More particularly, the torsion beam bridges the two support columns 12a, 12b and may be attached to the support columns by a bearing 16 and bearing housing 18 arrangement including any suitable fasteners. The torsion beam 14 may be any shape or configuration suitable for supporting a mounting rack, and in exemplary embodiments it has a square- or diamond-shaped cross section. A pivot axis 34 extends longitudinally through the torsion beam 14, and the torsion beam 14 may pivot or rotate about the pivot axis 34.

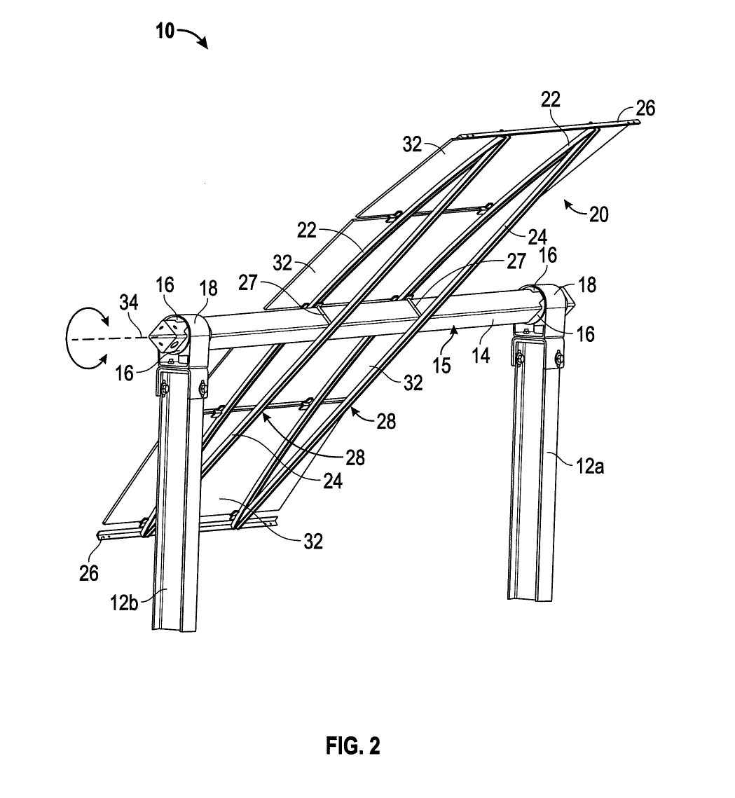

A mounting rack 20 is attached to the torsion beam 14. In exemplary embodiments, the mounting rack 20 includes front frame support 22 and rear frame support 24. The front frame support 22 is disposed upon a first side 13 of the torsion beam 14, and the rear frame support 24 is disposed upon a second opposite side 15 of the torsion beam 14. The front and rear frame supports 22, 24 of the mounting rack 20 may be held together by an end frame support 26, including a top and bottom end frame support 26a, 26b. As best seen in FIG. 2, a frame connector 27 may also be used to secure the connection of the frame support 22, 24 of the mounting rack 20 to the torsion beam 14.

Assembled in this way, the outer surface of the rear frame support 24 of the mounting rack 20 constitutes the rear surface 28 of the rack. Similarly, the outer surface of the front frame support 22 constitutes the mounting surface 30 of the mounting rack 20. The mounting rack 20 may be rotatably connected to the torsion beam 14 so it can be pivoted or rotated about the pivot axis 34. Alternatively, the mounting rack 20 could be fixedly attached to the torsion beam 14 to form a fixed mounting assembly or solar tracker. In exemplary embodiments, the mounting assembly is a solar tracker 10, and the components mounted to the mounting surface 30 of the mounting rack 20 are solar modules 32.

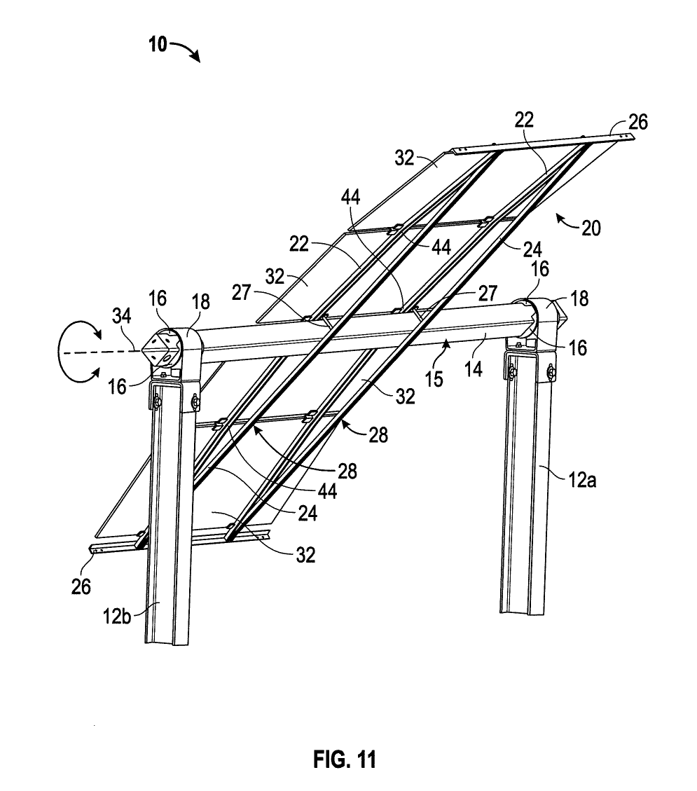

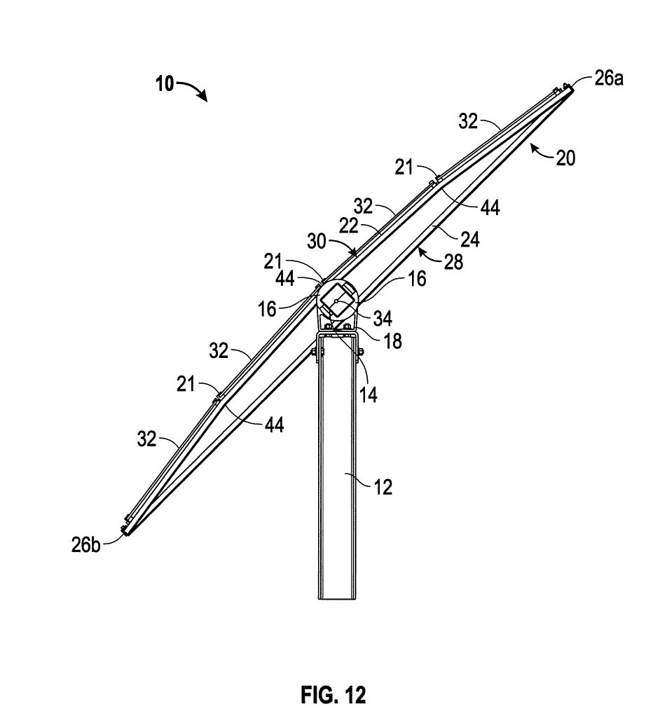

In exemplary embodiments, the front frame support 22 is a curved member which curves along its length as it extends across the torsion beam 14. As shown in FIGS. 11-12, another exemplary embodiment of a front frame support 22 of the mounting rack 20 includes one or more angles or bends 44 along its length instead of a continuous curve. Thus, the curved mounting surface 30 of the mounting rack 20 is achieved by the angles 44 in the front frame support 22. Each angle or bend 44 could be at a location corresponding to the edges of the mounting components 32 such as solar modules. Accordingly, “curved mounting surface” as used herein includes the front surface of a front frame support 22 that forms a curve by any structural features, including but not limited to a continuous curve along its length, one or more angles or bends along its length, one or more interrupted curves along its length, and/or one more shorter frame support members connected at angles to from a full frame support.

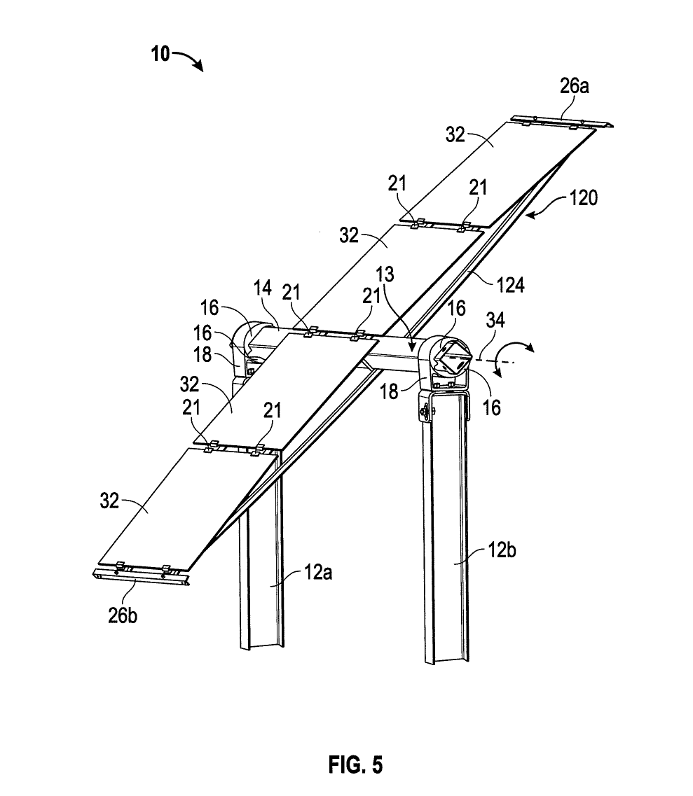

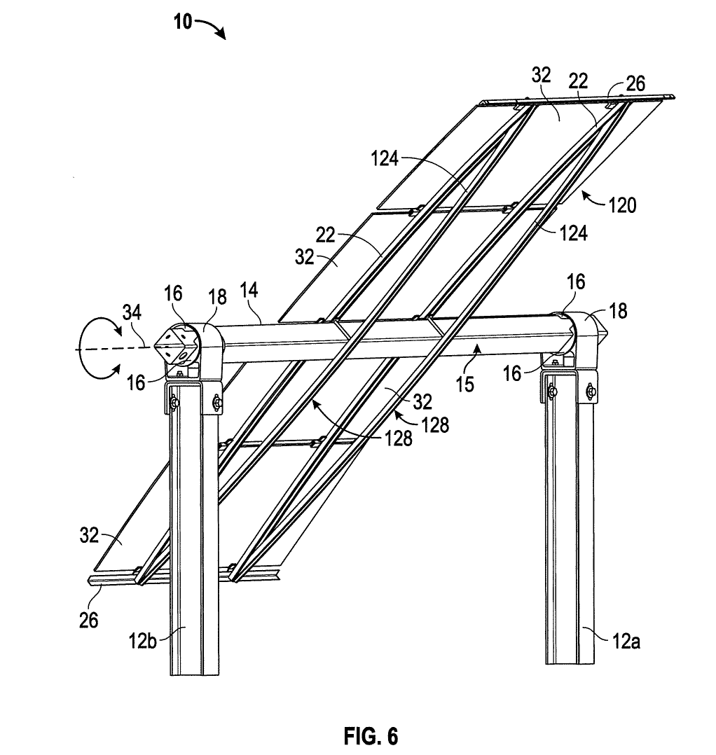

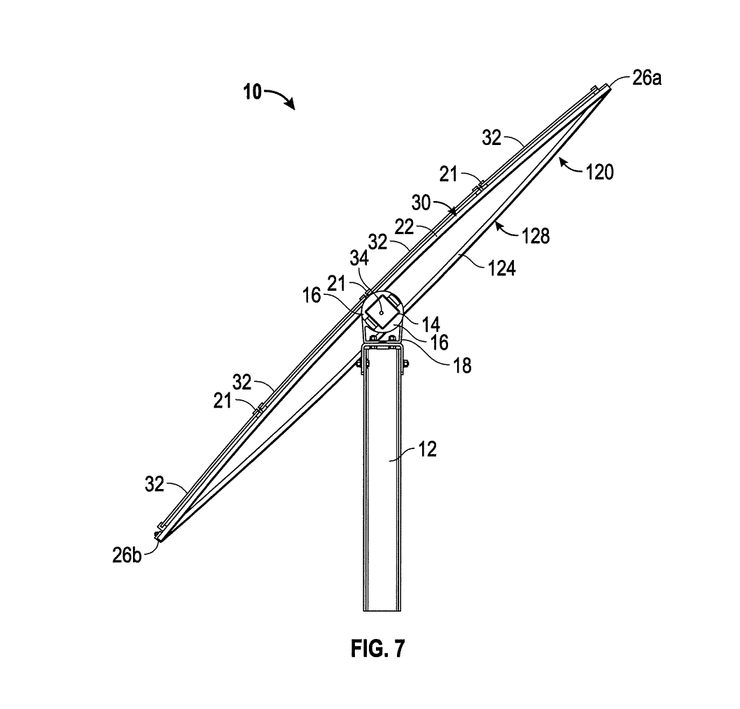

Exemplary rear frame supports 24 are substantially straight members. Thus, in exemplary embodiments, the mounting surface 30 of the mounting rack 20 is a curved surface, and the rear surface 28 of the mounting rack is substantially straight. As illustrated in FIGS. 5-7, exemplary embodiments of a mounting assembly or solar tracker 10 may have a modified mounting rack 120 including a rear frame support member 124 that is also a curved member like the front frame support 22. Thus, in such embodiments the rear frame support member 124 curves along its length as it extends across the torsion beam 14 and has a curved rear surface 128. It should be noted that the rear frame support member 124 could form a curve by any structural features, as discussed above. Otherwise, the embodiment shown in FIGS. 5-7 is substantially the same in structure and operation as described herein with reference to FIGS. 1-4.

Components such as solar modules 32 may be mounted to the curved mounting surface 30 of the mounting rack 20 using movable mounting clips 21. Due to the curved mounting surface 30 of the mounting rack 20, the weight of the solar modules or other components 32 mounted onto the mounting surface 30 is naturally shifted toward the pivot axis 34 that runs through the torsion beam 14. In other words, the curved mounting surface 30 of the mounting rack 20 advantageously moves the center of gravity of the mounting assembly 10 closer to the pivot axis 34 in the torsion beam 14, which results in less overhung weight in the mounting assembly 10. This balances the weight of the modules 32 more evenly over the rotating torsion beam 14 and results in less force required to rotate the mounting assembly or solar tracker 10.

When the overhung weight is reduced, the torque load about the pivot axis 34 is reduced in the mounting assembly 10. By bringing the center of gravity closer to the pivot axis 34, the effort or torque required to rotate the array of solar modules 32 during tracking may be reduced dramatically, even close to zero if fully balanced, as discussed below. This is an important feature when trying to minimize the number of motors and horsepower required to rotate a PV array in a solar tracking system. The lower the overhung weight on the system, the fewer and/or lower horsepower motors are required to rotate the array of solar modules 32. Fewer, and/or smaller motors in a solar tracking system means less cost to install and maintain the tracker over its lifetime. This equates to a lower lifetime cost of renewable energy production in a system.

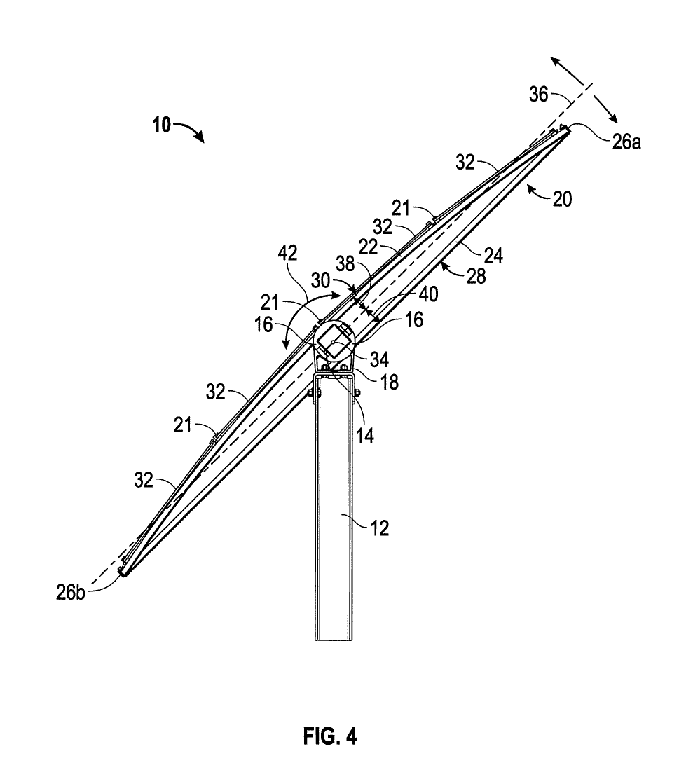

As best seen in FIG. 4, the mounting assembly 10 may have a balance axis 36, which runs perpendicular to the pivot axis 34 and intersects the pivot axis 34. The mounting assembly 10 further includes a first distance 38, which is the distance between the balance axis 36 and the curved mounting surface 30 of the mounting rack 20, and a second distance 40, which is the distance between the balance axis 36 and the rear surface 28 of the mounting rack 20. As mentioned above, the curved mounting surface 30 of the mounting rack 20 advantageously balances the weight of the solar modules 32.

This balanced configuration can be achieved when the weight X distance of the front of the mounting rack 20 is equal to the weight X distance of the rear of the mounting rack, about the balance axis 36. More particularly, the system is in balance when a first portion of the weight of the solar modules 32 or other mounted components above the balance axis 36 multiplied by the first distance 38 is substantially equal to a second portion of the weight of the solar modules 32 below the balance axis multiplied by the second distance 40. The first and second distances 38, 40 can be measured at different locations and multiple points along the solar modules 32 and along the front and rear surfaces 30, 28 of the mounting rack 20. Perfect balance is achieved in the mounting assembly 10 when:

$${\sum }_{i = 1}^{n} {m}_{i} {d}_{i} = 0$$

In this equation “n” represents the number of components in the mounting assembly, “m” represents the mass of each component, and “d” is the distance vector from the center of the tube to the center of gravity of each component. The skilled artisan would be able to calculate the Cg of the arc section using CAD software, for example. It should be noted, however, that the mounting assembly 10 does not need to be fully balanced to achieve the substantial weight reducing advantages discussed herein. Even some shifting of the weight or load short of perfect balancing yields significant benefits.

Another advantage derived by reducing the overhung weight of the array of solar modules 32 is that the natural resonant frequency of the solar tracker 10 is increased, thereby minimizing structural material required in the design. A higher resonant frequency keeps the solar tracker 10 from coupling into the wind and experiencing high dynamic loads. Dynamic loading can be extremely detrimental to the structural integrity of a tracking system. It is extremely important to minimize and eliminate dynamic loading in tracking system design. As discussed above, the curved mounting surface 30 of the mounting rack 20 balances the weight about the pivot axis 34 better, which increases the natural resonant frequency of the structure, thereby allowing less expensive structural designs. Less structural material equates to less cost. Minimizing material usage in a photovoltaic system also realizes earlier energy payback on the system.

The inherent stiffness of the curved front frame support 22 of the mounting rack 20 also results in minimization of material. In other words, the curved design of the mounting rack 20 also minimizes material necessary in the structure by drawing from the inherent structural stiffness of the arch. This design achieves higher strength and stiffness over a straight structural member since it directs some of the force into compression and tension instead of all the forces being directed into a bending moment.

It should be noted that some PV modules may perform slightly better when off track to the sun by a small amount. In exemplary embodiments in which the mounting surface 30 of the mounting rack 20 is curved, the modules will not all be on a single plane and therefore cannot all be perpendicular to the sun's rays during tracking. The area exposed to the sun can be calculated as the cosine of the off track angle. The area reduction effect of this gently curved surface is generally minimal. It is known that some thin film PV modules perform better when slightly off track to the sun. When this is the case, the curved mounting surface 30 of the mounting rack 20 may result in a higher output over a flat rack.

In operation, the user may reduce the torque load of exemplary solar trackers 10 by mounting solar modules 32 to the curved mounting surface 30 of the mounting rack 20. This will shift the load or weight of the solar modules 32 toward the pivot axis 34 in the torsion beam 14, thereby reducing the torque load about the pivot axis 34. More particularly, the load of the solar modules 32 is shifted such that the center of gravity of the mounting rack 20 and the modules 32 is at or near the pivot axis 34.

The user may balance the solar tracker 10 by rotating the mounting rack 20 such that a first portion of the weight of the solar modules 32 above the balance axis 36 multiplied by the first distance 38 is substantially equal to a second portion of the weight of the solar modules 32 below the balance axis multiplied by the second distance 40. As discussed above, the first distance 38 is the distance between the balance axis 36 and the curved mounting surface 30 of the mounting rack 20, and the second distance 40 is the distance between the balance axis 36 and the rear surface 28 of the mounting rack 20. This can reduce the effort or torque required to rotate the array of solar modules 32 during tracking dramatically, even close to zero. As best seen in FIG. 4, the solar tracker 10 may be rotated 42 to track the sun.

Thus, it is seen that improved mounting assemblies, solar trackers, and methods of reducing torque load are provided. It should be understood that any of the foregoing configurations and specialized components may be interchangeably used with any of the apparatus or systems of the preceding embodiments. Although illustrative embodiments are described hereinabove, it will be evident to one skilled in the art that various changes and modifications may be made therein without departing from the scope of the disclosure. It is intended in the appended claims to cover all such changes and modifications that fall within the true spirit and scope of the disclosure.

What is claimed is:

1. A mounting assembly comprising:
at least one support column;
a torsion beam connected to the support column, a longitudinal pivot axis extending through the torsion beam;
a mounting rack attached to the torsion beam;
wherein the mounting rack has a substantially flat mounting surface and a curved rear surface.

2. The mounting assembly of claim 1 wherein the mounted components comprise one or more solar modules.

3. The mounting assembly of claim 1 wherein the torsion beam is rotatably connected to the support column such that the mounting rack rotates about the pivot axis.

4. The mounting assembly of claim 1 wherein the mounting rack comprises a straight front frame support and a curved back frame support.

5. A solar tracker comprising:
at least one support column;
a torsion beam connected to the support column, a longitudinal pivot axis extending through the torsion beam;
a mounting rack attached to the torsion beam, the mounting rack having a curved rear surface and a substantially flat mounting surface; and
one or more solar modules mounted to the mounting surface of the mounting rack.

6. The solar tracker of claim 5 wherein the torsion beam is rotatably connected to the support column such that the mounting rack rotates about the pivot axis.

7. The solar tracker of claim 5 wherein the mounting rack comprises a substantially flat front frame support and a curved back frame support.

8. The solar tracker of claim 5 wherein the torsion beam is fixedly attached to the support column such that the mounting rack is in a fixed position relative to the support column.

9. The solar tracker of claim 5 wherein the mounting rack comprises a straight front frame support and a curved back frame support.

10. A mounting assembly comprising:
at least one support column;
a torsion beam connected to the support column, a longitudinal pivot axis extending through the torsion beam;
a mounting rack attached to the torsion beam;
wherein the mounting rack has a rear surface and a curved mounting surface such that a weight of one or more components mounted thereto is shifted toward the pivot axis.

11. The mounting assembly of claim 10 wherein the weight of the mounted components is shifted such that the center of gravity of the mounting rack and the components is at or near the pivot axis.

12. The mounting assembly of claim 11 further comprising a balance axis intersecting and perpendicular to the pivot axis;
wherein a balanced configuration is achieved when a first portion of the weight of the mounted components above the balance axis multiplied by a distance between the balance axis and the curved mounting surface is substantially equal to a second portion of the weight of the mounted components below the balance axis multiplied by a distance between the balance axis and the rear surface of the mounting rack.

13. The mounting assembly of claim 10 wherein the mounted components comprise one or more solar modules.

14. The mounting assembly of claim 10 wherein the torsion beam is rotatably connected to the support column such that the mounting rack rotates about the pivot axis.

15. The mounting assembly of claim 10 wherein the rear surface of the mounting rack is substantially straight.

16. The mounting assembly of claim 15 wherein the mounting rack comprises a curved front frame support and a straight back frame support.

17. The mounting assembly of claim 10 wherein the rear surface of the mounting rack is curved.

18. The mounting assembly of claim 17 wherein the mounting rack comprises a curved front frame support and a curved back frame support.

19. The mounting assembly of claim 16 wherein the curved front frame support includes one more angles along its length.

20. The mounting assembly of claim 18 wherein the curved back frame support includes one or more angles along its length.
